(19) United States
(12) Patent Application Publication
(10) Pub. No.: US 2009/0203171 A1
(43) Pub. Date: Aug. 13, 2009

(54) SEMICONDUCTOR DEVICE FABRICATING METHOD

(75) Inventors: Kengo TAKEMASA, Tokyo (JP); Makoto Terui, Yamanachi (JP); Yasushi Shiraishi, Tokyo (JP); Junji Tsuchimoto, Mie (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/338,534

(22) Filed: Dec. 18, 2008

(30) Foreign Application Priority Data
Dec. 27, 2007 (JP) 2007-337749

(51) Int. Cl. H01L 21/78

(52) U.S. Cl. 438/113; 257/E21.599

(57) ABSTRACT

A semiconductor device fabricating method includes forming a plurality of semiconductor devices that include one semiconductor chip and a metal plate having an opening portion that surrounds a region where the semiconductor chip is provided, by cutting, at regions where a frame portion exists, a plate-shaped member that includes: a wiring layer including a wiring portion and an insulating portion; a plurality of semiconductor chips disposed on one surface of the wiring layer; a metal plate disposed at a surface of the wiring layer at a side at which the semiconductor chips are provided, and having a plurality of opening portions that surround regions where the semiconductor chips are provided and the frame portion that forms the opening portions; and a sealing resin layer provided so as to seal at least gaps between the semiconductor chips and the metal plate.

### CROSS-REFERENCE TO RELATED APPLICATION

This application claims priority under 35 USC 119 from Japanese Patent Application No. 2007-337749, the disclosure of which is incorporated by reference herein.

### BACKGROUND OF THE INVENTION

1. Field of the Invention

The present invention relates to a semiconductor device fabricating method.

2. Description of the Related Art

A Tape-BGA package type semiconductor device is known as a package structure of a semiconductor device. This device has a structure in which a frame-shaped, metal member called a stiffener (reinforcing material) is disposed so as to surround a semiconductor chip. The stiffener is disposed at the reverse of a TAB tape having an inner lead that is connected by inner lead bonding to an electrode of the semiconductor chip, and functions to correct the warping thereof and ensure planarity.

There has been disclosed a technique that uses a stiffener molded from a synthetic resin material in order to make such a Tape-BGA package type semiconductor device lighter-weight and to simplify the fabricating processes thereof (refer to Japanese Patent Application Laid-Open (JP-A) No. 11-307592).

Other than in Tape-BGA package type semiconductor devices, a stiffener is used also in BAG package type semiconductor devices. For example, for the purposes of reducing the amount of warping of the substrate at the time of mounting, and, at the time of temperature cycle testing, preventing destruction of the solder bumps and the like that connect a semiconductor chip and the mounting substrate and suppressing cracking of the mounting substrate, there has been proposed a semiconductor device having a reinforcing material, where the thermal expansion coefficient of the resin of an underfill portion provided at the lower portion of the semiconductor chip and the thermal expansion coefficient of a sealing resin used for sealing the gap between the semiconductor chip and the reinforcing material are small (see, for example, JP-A No. 2004-260138).

However, semiconductor devices provided with conventional stiffeners are fabricated via a process of respectively placing stiffeners corresponding to the individual semiconductor chips on the substrate to which the semiconductor chips are mounted. Therefore, at the time of fabricating a semiconductor device, there is the need to place the stiffeners corresponding to the individual semiconductor chips on the substrate, and the production efficiency is poor.

Further, due to the existence of the stiffener, warping of the semiconductor device that is finally obtained is suppressed. However, in the semiconductor device fabrication processes, at the stage before the individual semiconductor devices are cut-out by cutting, the individual stiffeners are independent. Therefore, after the resin layer for sealing is formed on the substrate that is in the state in which the plural semiconductor chips are mounted thereon, warping may arise in the substrate overall due to contraction of this resin layer. Depending on the structure of the semiconductor devices and on the fabricating process thereof as well, the occurrence of such warping may give rise to various bad effects. For example, in a case of fabricating semiconductor devices by flip-chip joining the semiconductor chips, it is easy for poor flip-chip joining to arise, and, as a result, a decrease in the yield of the semiconductor devices may be brought about.

### SUMMARY OF THE INVENTION

The present invention was made in view of the above-described circumstances, and an object thereof is to provide a semiconductor device fabricating method that has high production efficiency and suppresses the occurrence of warping in the fabricating processes as well.

This object is achieved by the present invention as follows. Namely, the present invention provides a semiconductor device fabricating method for forming a plurality of semiconductor devices that each include one semiconductor chip and a metal plate having an opening portion that surrounds a region where the semiconductor chip is provided, the method comprising cutting, at regions where a frame portion exists, a plate-shaped member that includes:

a wiring layer including a wiring portion and an insulating portion;

a plurality of semiconductor chips disposed on one surface of the wiring layer;

a metal plate disposed at a surface of the wiring layer at a side at which the semiconductor chips are provided, and having a plurality of opening portions that surround regions where the semiconductor chips are provided and the frame portion that forms the opening portions; and

a sealing resin layer provided to seal at least gaps between the semiconductor chips and the metal plate.

As described above, in accordance with the present invention, there can be provided a semiconductor device fabricating method that has high production efficiency and suppresses the occurrence of warping in the fabricating processes as well.

### BRIEF DESCRIPTION OF THE DRAWINGS

Preferred exemplary embodiments of the present invention will be described in detail based on the following figures, wherein:

FIGS. 1A through 1G are schematic model diagrams showing an example of a semiconductor device fabricating method of the present invention;

FIGS. 2A through 2C are schematic model diagrams showing another example of the semiconductor device fabricating method of the present invention;

FIGS. 3A through 3G are schematic model diagrams showing yet another example of the semiconductor device fabricating method of the present invention;

FIG. 4 is a model diagram showing an example of a semiconductor device that is fabricated in accordance with the semiconductor device fabricating method of the present invention;

FIGS. 5A through 5C are schematic model diagrams showing still another example of the semiconductor device fabricating method of the present invention;

FIGS. 6A and 6B are model diagrams showing an example of a planar shape of a metal plate 40;

FIGS. 7A and 7B are another example of enlarged views in which the region designated by reference letter A in FIG. 6A is enlarged; and

FIGS. 8A and 8B are yet another example of enlarged views in which the region designated by reference letter A in FIG. 6A is enlarged.

### DETAILED DESCRIPTION OF THE INVENTION

The present invention does not use metal plates corresponding respectively to individual semiconductor chips. Therefore, the efficiency of fabricating the plate-shaped member can be improved. As a result, the efficiency of producing semiconductor devices also can be improved. Further, at the time of fabricating the plate-shaped member, warping that is caused by contraction of resin in a case in which a sealing resin layer is formed, also can be suppressed. Therefore, various bad effects (e.g., a decrease in yield due to the occurrence of poor joining in a case of flip-chip joining the semiconductor chips, and the like) that accompany the occurrence of warping of the plate-shaped member that is in the midst of fabrication or in a completed state, can be suppressed.

Note that, from the standpoints of improving the production efficiency and suppressing warping, it is particularly preferable that the metal plate be formed from a single member (a member having opening portions that correspond to the total number of semiconductor chips mounted to the plate-shaped member) that corresponds to the size of the plate-shaped member.

However, from the standpoints of ensuring the handling ability and the accuracy of aligning the semiconductor chips and the opening portions, the metal plate may be a member that is, for example, one-half or one-quarter of the size of the plate-shaped member (may be a member having a number of opening portions that is one-half or one-quarter of the total number of the semiconductor chips mounted to the plate-shaped member). Therefore, in a case in which the metal plate is one-half of the size, the plate-shaped member is fabricated by using two metal plates, and in a case in which the metal plate is one-quarter of the size, the plate-shaped member is fabricated by using four metal plates.

However, in a case in which there are plural metal plates structuring the plate-shaped member, if the size of the individual metal plates is small, the production efficiency decreases and it is difficult to suppress warping. Therefore, the surface area of the individual metal plate (this surface area means the surface area including the opening portions and the frame portion) is preferably greater than or equal to ¼ of the surface area of the plate-shaped member, and greater than or equal to ½ is even more preferable.

In the process of forming the plural semiconductor devices by cutting the plate-shaped member at regions where the frame portion exists, a known cutting method can be used, but it is preferable to use dicing.

Further, it is preferable to provide concave portions and/or holes in the frame portion of the metal plate. In this case, in the process of forming the plural semiconductor devices, the cutting speed can be improved by carrying out the cutting of the regions where the frame portion exists, along the portions where the concave portions and/or holes, that are provided in the frame portion, are provided. Moreover, wear of the member that is used in cutting (the dicing blade) also can be suppressed. Note that the concave portions or holes can be formed by using press machining, etching processing, or the like.

The material structuring the metal plate is not particularly limited, and a known metal material can be used. For example, Cu, Al, alloys including these metals, and SUS can be used. There among, it is preferable to use SUS that has a low thermal expansion coefficient.

Note that the method of fabricating the plate-shaped member is not particularly limited, but it is preferable that the plate-shaped member be fabricated through the following processes.

Namely, the plate-shaped member is preferably fabricated via at least following processes (1) through (5):
(1) preparing a supporting substrate that includes a semiconductor substrate and a wiring layer that is formed on a surface of the semiconductor substrate and includes an insulating portion and a wiring portion;
(2) mounting a plurality of semiconductor chips to a surface of the supporting substrate at a side at which the wiring layer is provided;
(3) placing a metal plate, that has a plurality of opening portions and a frame portion forming the opening portions, at the surface of the supporting substrate at the side at which the wiring layer is provided, at (3a) a position at which the opening portions surround individual semiconductor chips or (3b) a position at which the opening portions surround predetermined regions where individual semiconductor chips are to be disposed;
(4) forming a sealing resin layer so as to seal at least gaps between the semiconductor chips and the metal plate; and
(5) removing the semiconductor substrate from the supporting substrate.

Note that, in process (4), the sealing resin layer can be formed by a molding method or a potting method. Further, when a molding method is employed, the sealing resin layer can be formed not only at the gap portions between the semiconductor chips and the metal plate, but also so as to cover these both members.

Hereinafter, when implementing above processes (1) through (5) in that order, in process (4), a case that employs a molding method will be called a “first exemplary embodiment”, and a case employing a potting method will be called a “second exemplary embodiment”.

The above five processes can be executed in the order of their numbers as described above, but are not limited to the same.

In a case in which the above five processes are not implemented in the order of their numbers, process (1) among these five processes must be executed first, but the remaining processes (2) through (5) can be executed in an arbitrary order provided that the following conditions are satisfied. First, either of processes (2) and (3) may be executed before the other. However, if process (2) is implemented first, process (3a) is selected, and if process (2) is executed after, process (3b) is selected. Further, process (4) can be executed at an arbitrary time provided that it is after processes (2) and (3) have been executed. Further, process (5) can be executed at an arbitrary time provided that it is after process (1) has been executed.

Other than implementing processes (1) through (5) in that order, another suitable combination of the order of execution when executing processes (1) through (5) is, for example, (1) in the process of preparing the supporting substrate, forming plural opening portions in the wiring layer, (3) placing the metal plate, that has plural opening portions and a frame portion forming the opening portions, at the surface of the supporting substrate at the side at which the wiring layer is provided, at a position of surrounding predetermined regions where the individual semiconductor chips are to be disposed, and thereafter, (5) carrying out the process of removing the semiconductor substrate from the supporting substrate, and (2) then, mounting the plural semiconductor chips to the surface of the wiring layer at the side at which the metal plate is provided, so as to seal the opening portions of the wiring layer, and thereafter, (4) carrying out the process of forming the sealing resin layer (hereinafter, an aspect embodied by this combination is called a “third exemplary embodiment”).

The method of connecting the semiconductor chips to the wiring layer is not particularly limited, and flip-chip joining or wire bonding can be selected. In the case of flip-chip joining, the flip-chip joining is carried out simultaneously with implementation of process (2), by using semiconductor chips with bump electrodes. Further, in the case of carrying out wire bonding, the wire bonding is carried out after process (2) is implemented and before process (3) is implemented.

At the semiconductor device that is fabricated by the semiconductor device fabricating method of the present invention, a heat sink (heat dissipating plate) can be provided at the surface at the side opposite the surface at the side where the wiring layer is provided. A plate formed from metal such as, for example, Cu, Al, alloys including these metals, SUS, or the like, can be used as the heat sink.

### First Exemplary Embodiment

A concrete example of the semiconductor device fabricating method of the present invention will be described in further detail hereinafter by using the drawings.

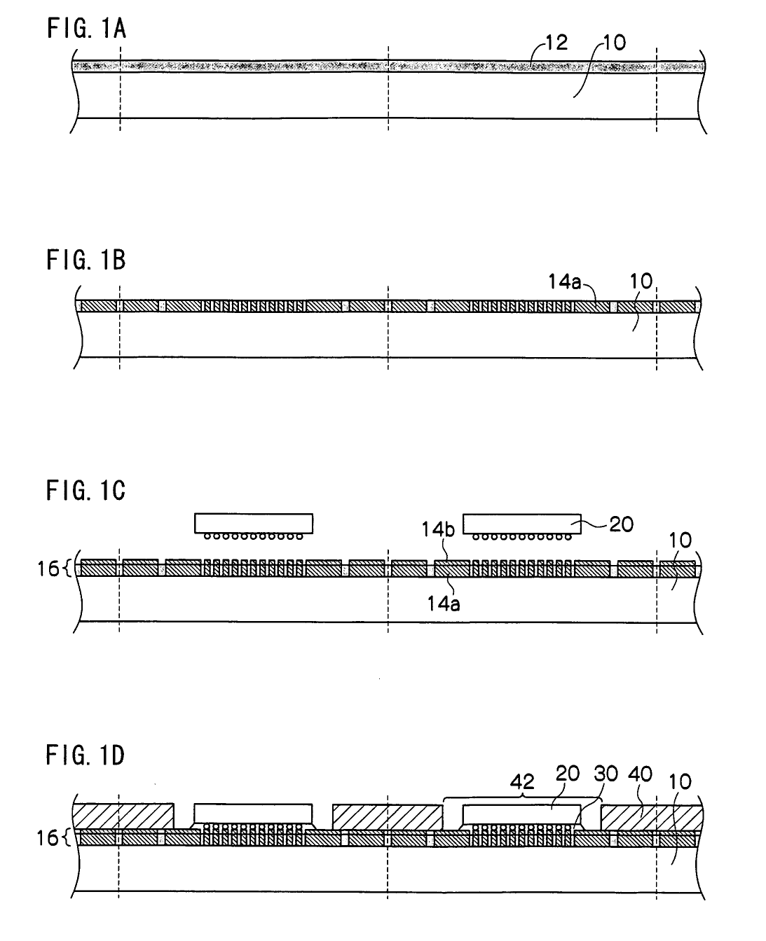

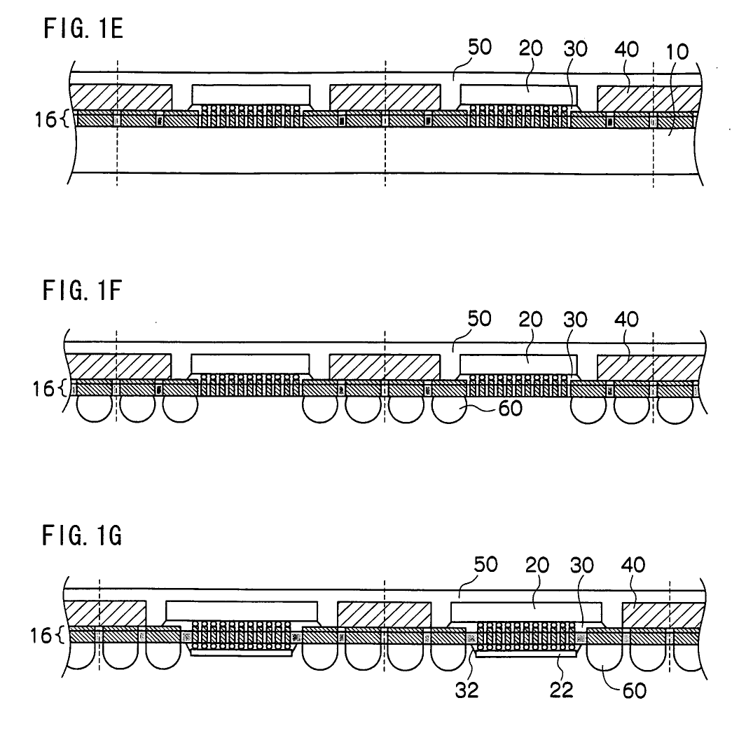

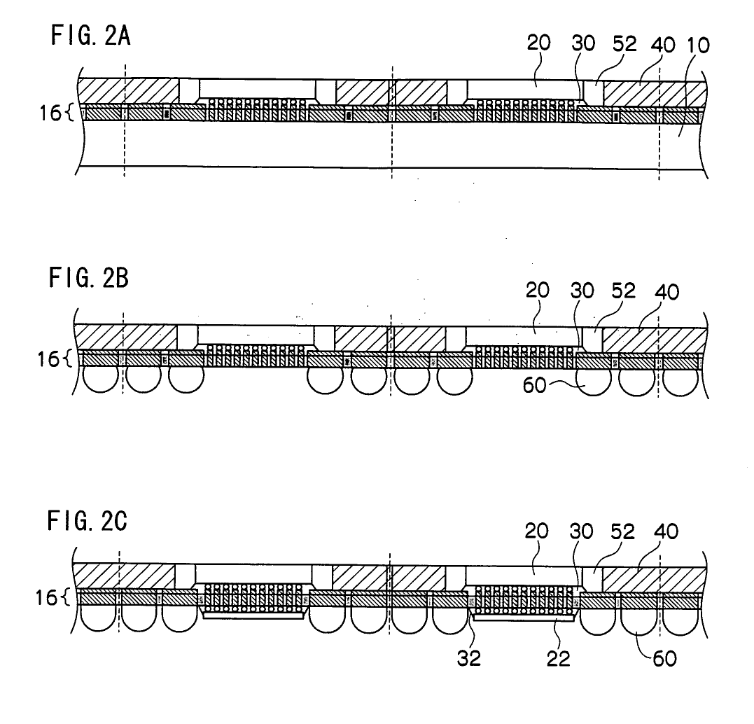

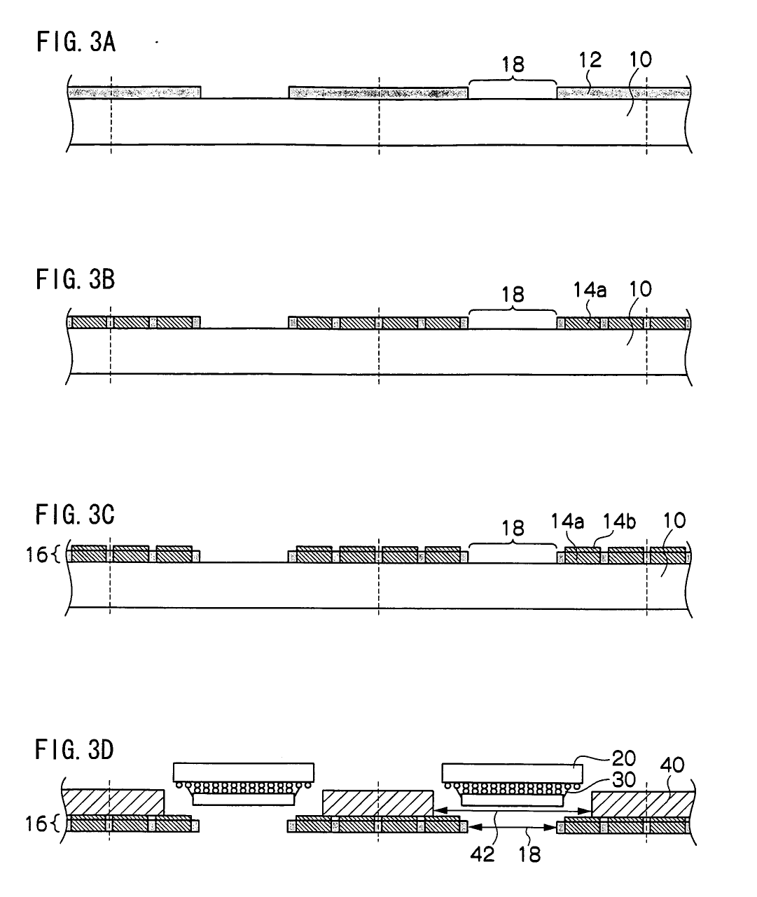

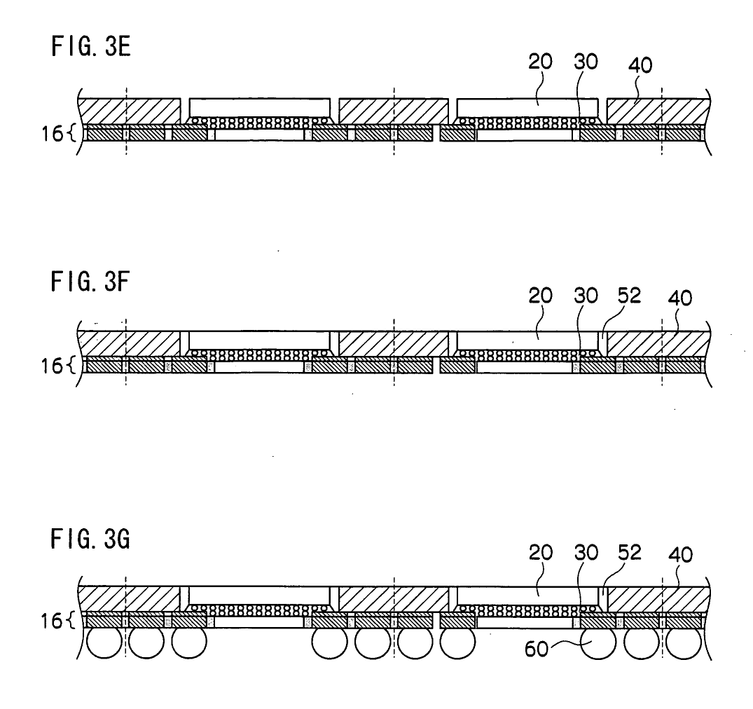

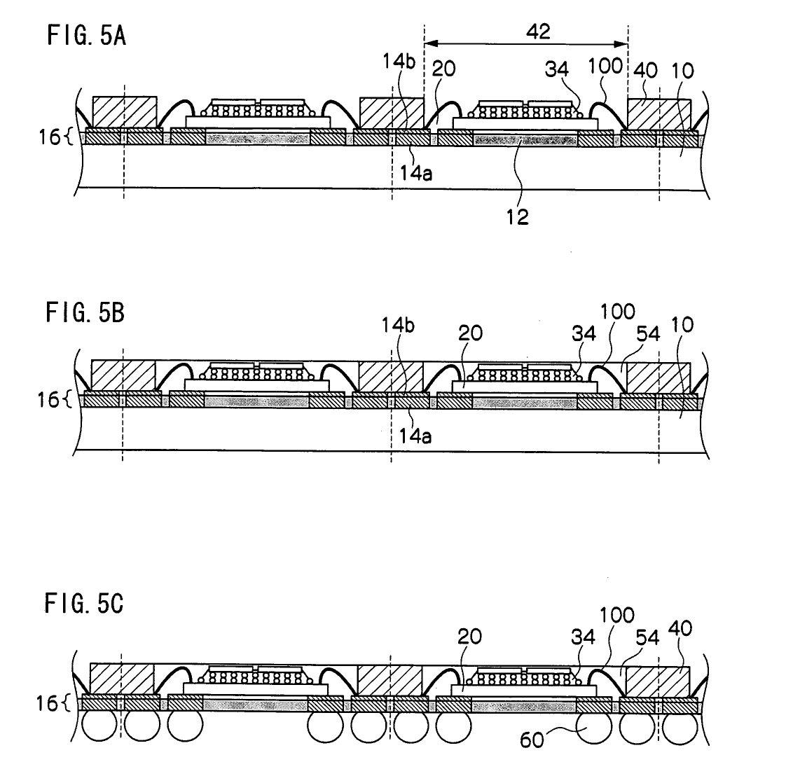

FIG. 1 is a schematic model diagram showing an example of the semiconductor device fabricating method of the present invention, and illustrates a concrete example of the first exemplary embodiment. Note that FIG. 1 is for explaining a state before a plate-shaped member is cut at the lines shown by the dashed lines in the drawing and is made into members of sizes corresponding to the individual semiconductor devices (the same holds for FIG. 2, FIG. 3 and FIG. 5 that will be described hereinafter).

In the drawing, reference numeral 10 is a semiconductor substrate 10 such as a silicon wafer or the like, 12 is an insulating layer formed from polyimide or the like, 14a is conductor rewiring (the first layer), 14b is conductor rewiring (the second layer), 16 is a wiring layer, 20 and 22 are semiconductor chips with bump electrodes, 30 and 32 are underfill, 40 is a metal plate (frame portion), 42 is an opening portion, 50 is a sealing resin layer, and 60 is a terminal.

In the example shown in FIG. 1, semiconductor devices are fabricated as follows.

First, the insulating layer 12 is formed on the surface of the semiconductor substrate 10 (FIG. 1A), and next, the conductor rewiring (first layer) 14a is formed (FIG. 1B), and then the conductor rewiring 14b (second layer) is formed. A supporting substrate that includes the semiconductor substrate 10 and the wiring layer 16, that is formed on the surface of the semiconductor substrate 10 and has an insulating portion and a wiring portion, is thereby prepared (FIG. 1C).

Next, semiconductor chips 20 with bump electrodes, at which bump electrodes are provided on one surface thereof, are readied. These plural semiconductor chips 20 with bump electrodes are disposed on the wiring layer 16 side surface of the supporting substrate such that the surfaces thereof at which the bump electrodes are formed face the wiring layer 16, and are flip-chip joined (FIGS. 1C, 1D). Then, resin is injected/filled in the gaps between the wiring layer 16 and the semiconductor chips 20 with bump electrodes by a method of dropping using a dispenser or the like. Thereafter, the resin is hardened so as to form the underfill 30 (FIG. 1D).

Then, the metal plate 40, that has the plural opening portions 42 and the frame portion that forms these opening portions 42, is disposed at the wiring layer 16 side surface of the supporting substrate at a position such that the opening portions 42 surround the semiconductor chips 20 (FIG. 1D). Note that the wiring layer 16 and the metal plate 40 are joined via an adhesive.

Thereafter, the sealing resin layer 50 is formed by a molding method at the gaps between the semiconductor chips 20 and the metal plate 40, and so as to cover the semiconductor chips 20 and the metal plate 40 (FIG. 1E). Next, the semiconductor substrate 10 is peeled off from the wiring layer 16, and the terminals 60 are formed at the surface of the wiring layer 16 at the side where the semiconductor substrate 10 was provided (FIG. 1F). Finally, the semiconductor chips 22 having bump electrodes, at which bump electrodes are provided at one surface thereof, are disposed at the surface of the wiring layer 16 at the side where the semiconductor substrate 10 was provided, such that the surfaces thereof at which the bump electrodes are provided face the wiring layer 16, and are flip-chip joined. Thereafter, resin is injected/filled into the gaps between the wiring layer 16 and the semiconductor chips 22 by a method of dropping by using a dispenser or the like, and the resin is hardened so as to form the underfill 32 (FIG. 1G). The plate-shaped member is thereby completed.

Then, the semiconductor devices are obtained (not illustrated) by cutting this plate-shaped member by dicing or the like at the portions, that are shown by the dashed lines in the drawing, of the regions where the frame portion 40 exists.

### Second Exemplary Embodiment

FIG. 2 is a schematic model diagram showing another example of the semiconductor device fabricating method of the present invention, and illustrates a concrete example of the second exemplary embodiment.

In the drawing, reference numeral 52 is a sealing resin layer, and members denoted by other reference numerals are the same as in FIG. 1.

In the example shown in FIG. 2, semiconductor devices are fabricated as follows.

First, the processes shown in FIG. 1A through FIG. 1D are implemented in order. Next, the sealing resin layer 52 is formed by a potting method by using a dispenser or the like at the gaps between the semiconductor chips 20 and the metal plate 40 (FIG. 2A).

Then, the semiconductor substrate 10 is peeled off from the wiring layer 16, and the terminals 60 are formed at the surface of the wiring layer 16 at the side where the semiconductor substrate 10 was provided (FIG. 2B). Finally, the semiconductor chips 22 having bump electrodes, at which bump electrodes are provided at one surface thereof, are disposed at the surface of the wiring layer 16 at the side where the semiconductor substrate 10 was provided, such that the surfaces thereof at which the bump electrodes are provided face the wiring layer 16, and are flip-chip joined. Thereafter, resin is injected/filled into the gaps between the wiring layer 16 and the semiconductor chips 22 by a method of dropping by using a dispenser or the like, and the resin is hardened so as to form the underfill 32 (FIG. 2C). The plate-shaped member is thereby completed.

Then, the semiconductor devices are obtained (not illustrated) by cutting this plate-shaped member by dicing or the like at the portions, that are shown by the dashed lines in the drawing, of the regions where the frame portion 40 exists.

### Third Exemplary Embodiment

FIG. 3 is a schematic model diagram showing yet another example of the semiconductor device fabricating method of the present invention, and illustrates a concrete example of the third exemplary embodiment.

In the drawing, reference numeral 18 is an opening portion, and members denoted by other reference numerals are the same as in FIG. 1 and FIG. 2.

In the example shown in FIG. 3, semiconductor devices are fabricated as follows.

First, the insulating layer 12 is formed on the surface of the semiconductor substrate 10, and the opening portions 18 are provided at the portions where the semiconductor chips 20 are to be placed (FIG. 3A). Next, by forming the conductor rewiring (first layer) 14a (FIG. 3B) and then the conductor rewiring 14b (second layer) at the regions where the insulating layer 12 is provided, the supporting substrate is thereby prepared that includes the semiconductor substrate 10, and the wiring layer 16 formed on the surface of the semiconductor substrate 10 and having an insulating portion and a wiring portion, and at which the opening portions 18 are provided in the wiring layer 16 (FIG. 3C).

Next, the semiconductor chips 20 with bump electrodes, at which bump electrodes are provided on one surface thereof, are readied. Note that the underfill 30 is formed in advance at the surfaces of the semiconductor chips at the sides where the bump electrodes are provided.

Thereafter, the metal plate 40, that has the plural opening portions 42 and the frame portion that forms these opening portions 42, is disposed at the wiring layer 16 side surface of the supporting substrate at a position such that the opening portions 42 surround the predetermined regions where the semiconductor chips 20 are to be disposed (FIG. 3D). Note that the wiring layer 16 and the metal plate 40 are joined via an adhesive.

Next, the plural semiconductor chips 20 with bump electrodes are disposed on the wiring layer 16 side surface of the supporting substrate such that the surfaces thereof at which the bump electrodes are formed close-up the opening portions 18 of the wiring layer 16 (FIG. 3E).

Thereafter, the sealing resin layer 50 is formed by a potting method at the gaps between the semiconductor chips 20 and the metal plate 40 (FIG. 3F). Finally, the semiconductor substrate 10 is peeled off from the wiring layer 16, and the terminals 60 are formed at the surface of the wiring layer 16 at the side where the semiconductor substrate 10 was provided (FIG. 3G). The plate-shaped member is thereby completed.

Then, the semiconductor devices are obtained (not illustrated) by cutting this plate-shaped member by dicing or the like at the portions, that are shown by the dashed lines in the drawing, of the regions where the frame portion 40 exists.

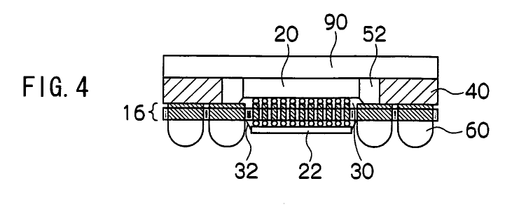

Note that, after any of the processes shown in FIG. 2A through FIG. 2C is finished, or after any of the processes shown in FIG. 3F through 3G is finished, a heat dissipating plate formed from a metal member may be mounted by using an adhesive or the like to the surface that is formed by the metal plate 40, the semiconductor chips 20, and the sealing resin layer 52. Semiconductor devices having heat dissipating plates 90 such as shown in FIG. 4 for example, can thereby be obtained. In this case, warping of the plate-shaped member in the midst of fabrication or of the obtained semiconductor devices can be suppressed even more. Note that members other than reference numeral 90 in FIG. 4 are the same as in FIGS. 2 and 3, and FIG. 4 illustrates a device that is in the state of a completed product that has been made into an individual piece.

Further, in the examples shown in FIGS. 1 through 3, flip-chip joining is carried out at the time of connecting the semiconductor chips to the wiring layer, but wire bonding may be employed.

FIG. 5 is a schematic model diagram showing yet another example of the semiconductor device fabricating method of the present invention, and shows an example of a case in which the semiconductor chips and the wiring layer are connected by wire bonding. In FIG. 5, reference numeral 34 is underfill, 54 is a sealing resin layer, and 100 is a wire, and the other members are the same as in FIGS. 1 through 3.

In the example shown in FIG. 5, semiconductor devices are fabricated as follows.

First, the processes shown in FIG. 1A through FIG. 1C are implemented in order so as to fabricate the supporting substrate at which the wiring layer 16 is formed on the surface of the semiconductor substrate 10. Note that the structure of the wiring layer 16 is selected appropriately so as to suit wire bonding.

Next, the semiconductor chips 20 with bump electrodes, at which bump electrodes are provided on one surface thereof, are readied. Note that the underfill 34 is formed in advance at the surfaces of the semiconductor chips 20 at the sides where the bump electrodes are provided.

Thereafter, the metal plate 40, that has the plural opening portions 42 and the frame portion that forms these opening portions 42, is disposed at the wiring layer 16 side surface of the supporting substrate at a position such that the opening portions 42 surround the predetermined regions where the semiconductor chips 20 are to be disposed (FIG. 5A). Note that the wiring layer 16 and the metal plate 40 are joined via an adhesive.

Next, the plural semiconductor chips 20 with bump electrodes are disposed on the wiring layer 16 side surface of the supporting substrate such that the surfaces thereof at which the bump electrodes are formed are at the side opposite the wiring layer 16. Note that the semiconductor chips 20 and the wiring layer 16 are joined via an adhesive. Thereafter, the conductor rewiring 14b, that structures the wiring layer 16, and the semiconductor chips 20 are wire-bonded by the wires 100. Note that the placing of the metal plate 40 on the one hand, and the placing of the semiconductor chips 20 and the wire bonding on the other hand, may be implemented in the reverse order.

Thereafter, the sealing resin layer 54 is formed by filling resin by using a potting method so as to seal the interiors of the opening portions 42 of the metal plate 40 and cover the semiconductor chips 20. Next, the semiconductor substrate 10 is peeled off from the wiring layer 16, and the terminals 60 are formed at the surface of the wiring layer 16 at the side where the semiconductor substrate 10 was provided (FIG. 5C). The plate-shaped member is thereby completed.

Then, the semiconductor devices are obtained (not illustrated) by cutting this plate-shaped member by dicing or the like at the portions, that are shown by the dashed lines in the drawing, of the regions where the frame portion 40 exists.

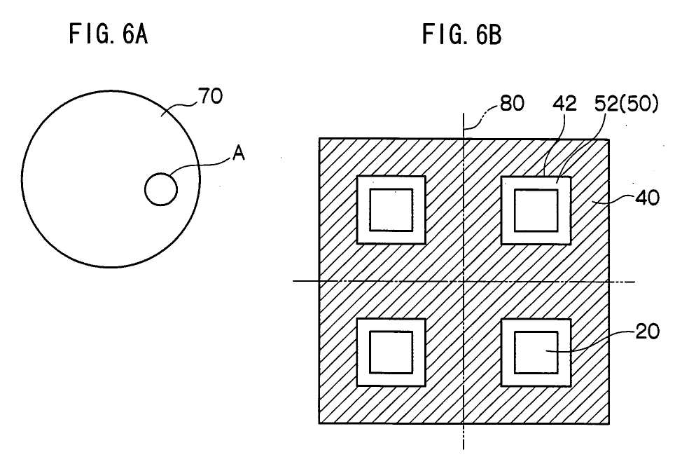

FIG. 6 is a model diagram showing an example of the planar shape of the metal plate 40, and illustrates a state in which the metal plate 40 structures a portion of the plate-shaped member. In the drawing, reference numeral 70 is a plate-shaped member and reference numeral 80 is a cutting line, and the other reference numerals are the same as in FIGS. 1 through 3.

Further, FIG. 6A is a plan view of the plate-shaped member, and FIG. 6B is an example of an enlarged view in which the region shown by reference letter A in FIG. 6A is enlarged. For example, FIG. 6B corresponds to a drawing in which the plate-shaped member illustrated in FIG. 2C or FIG. 3G is seen from the surface of the wiring layer 16 at the side where the semiconductor chips 20 and the metal plate is disposed, or corresponds to a drawing in which, in the plate-shaped member shown in FIG. 1G, the sealing resin layer 50 that covers the metal plate 40 and the semiconductor chips 20 is removed and the metal plate 40 and the semiconductor chips 20 are observed in an exposed state.

In the example shown in FIG. 6, the metal plate 40 is disposed such that the respective semiconductor chips 20, that are square-arrayed, are positioned at the centers of the opening portions 42 that are square. Further, the cutting lines 80 are provided in the frame portion so as to pass through intermediate points of two of the semiconductor chips 20 that are adjacent. By cutting along these cutting lines 80, the individual semiconductor devices can be obtained.

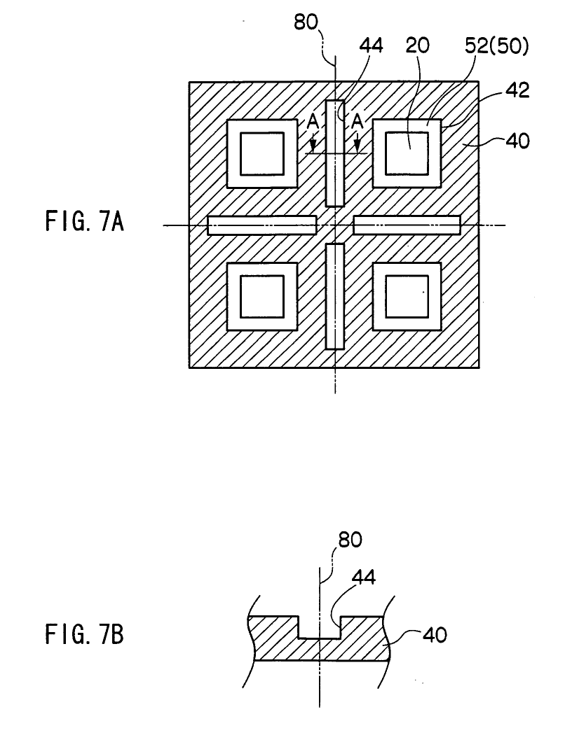

FIG. 7 is another example of enlarged views in which the region designated by reference letter A in FIG. 6A is enlarged. In the drawing, reference numeral 44 denotes a concave portion, and the other members are the same as shown in FIGS. 1 through 4. Here, FIG. 7A shows another example of an enlarged view in which the region designated by reference letter A in FIG. 6A is enlarged, and FIG. 7B is a cross-sectional view of the metal plate 40 that exists on the line marked A-A in FIG. 7A.

The concave portions 44, that are rectangular and extend along the cutting lines 80, are provided in the metal plate 40 shown in FIG. 7. As shown in FIG. 7A, the concave portions 44 can be provided along the cutting lines 80 other than at, for example, portions where the vertical direction cutting lines 80 and the lateral direction cutting lines 80 intersect. However, the concave portions 44 are not limited to the same, and the widths (the lengths in the directions orthogonal to the cutting lines 80) and lengths (the lengths in the directions parallel to the cutting lines 80) of the concave portions can be selected appropriately.

The concave portions 44 may be provided at one surface side of the metal plate 40 as shown in FIG. 7B, or may be provided at both surfaces.

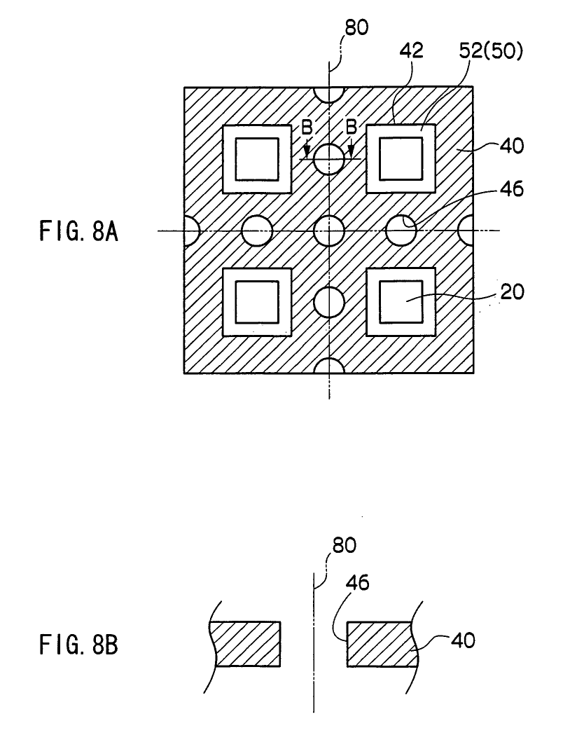

FIGS. 8A and 8B are another example of enlarged views in which the region designated by reference letter A in FIG. 6A is enlarged. In the drawings, reference numeral 46 denotes a hole, and the other members are the same as shown in FIGS. 1 through 5. Here, FIG. 8A shows another example of an enlarged view in which the region designated by reference letter A in FIG. 6A is enlarged, and FIG. 8B is a cross-sectional view of the metal plate 40 that exists on the line marked B-B in FIG. 8A. The holes 46 that are circular are provided on the cutting lines 80 at the metal plate 40 shown in FIGS. 8A and 8B. As shown in FIG. 8A, the holes 46 can be provided, for example, at the points of intersection of the vertical direction cutting lines 80 and the lateral direction cutting lines 80, and at intermediate points between two adjacent points of intersection. However, the arrangement of the holes 46 is not limited to the same, and can be selected appropriately together with the shapes and sizes and the like of the holes.

What is claimed is:

1. A semiconductor device fabricating method for forming a plurality of semiconductor devices that each include one semiconductor chip and a metal plate having an opening portion that surrounds a region where the semiconductor chip is provided, the method comprising cutting, at regions where a frame portion exists, a plate-shaped member that includes:
a wiring layer including a wiring portion and an insulating portion;
a plurality of semiconductor chips disposed on one surface of the wiring layer;
a metal plate disposed at a surface of the wiring layer at a side at which the semiconductor chips are provided, and having a plurality of opening portions that surround regions where the semiconductor chips are provided and the frame portion that forms the opening portions; and
a sealing resin layer provided to seal at least gaps between the semiconductor chips and the metal plate.

2. The semiconductor device fabricating method of claim 1, wherein the plate-shaped member is fabricated by at least:
(1) preparing a supporting substrate that includes a semiconductor substrate and a wiring layer that is formed on a surface of the semiconductor substrate and includes an insulating portion and a wiring portion;
(2) mounting a plurality of semiconductor chips on a surface of the supporting substrate at a side at which the wiring layer is provided;
(3) placing a metal plate, that has a plurality of opening portions and a frame portion forming the opening portions, at the surface of the supporting substrate at the side at which the wiring layer is provided, at a position at which the opening portions surround individual semiconductor chips or a position at which the opening portions surround predetermined regions where individual semiconductor chips are to be disposed;
(4) forming a sealing resin layer so as to seal at least gaps between the semiconductor chips and the metal plate; and
(5) removing the semiconductor substrate from the supporting substrate.

3. The semiconductor device fabricating method of claim 2, wherein the removing of the semiconductor substrate from the supporting substrate is carried out after the forming of the sealing resin layer.

4. The semiconductor device fabricating method of claim 3, wherein the preparing of the supporting substrate includes:
forming a plurality of opening portions in the wiring layer,
placing a metal plate, that has a plurality of opening portions and a frame portion forming the opening portions, at a surface of the supporting substrate at a side at which the wiring layer is provided, at a position at which the opening portions surround predetermined regions where individual semiconductor chips are to be disposed, and thereafter,
removing the semiconductor substrate from the supporting substrate, and then,
forming the sealing resin layer after mounting a plurality of semiconductor chips to a surface of the wiring layer at a side at which the metal plate is provided, so as to seal the opening portions of the wiring layer.

5. The semiconductor device fabricating method of claim 2, wherein the sealing resin layer is formed by a molding method or a potting method.

6. The semiconductor device fabricating method of claim 1, wherein
concave portions and/or holes are provided in the frame portion of the metal plate, and
in the forming of the plurality of semiconductor devices, cutting of the regions at which the frame portion exists is carried out along the concave portions and/or holes that are provided in the frame portion.

7. A semiconductor device fabricating method comprising:
a) preparing a supporting substrate that includes a semiconductor substrate and a wiring layer that is formed on a surface of the semiconductor substrate and includes an insulating portion and a wiring portion;
b) mounting a plurality of semiconductor chips on a surface of the supporting substrate at a side at which the wiring layer is provided;
c) placing a metal plate, that has a plurality of opening portions and a frame portion forming the opening portions, at the surface of the supporting substrate at the side at which the wiring layer is provided, at a position at which the opening portions surround individual semiconductor chips or a position at which the opening portions surround predetermined regions where individual semiconductor chips are to be disposed;
d) forming a sealing resin layer so as to seal at least gaps between the semiconductor chips and the metal plate;
e) removing the semiconductor substrate from the supporting substrate; and
f) forming a plurality of semiconductor devices that each include one semiconductor chip and a metal plate having an opening portion that surrounds a region where the semiconductor chip is provided, by cutting regions where the frame portion exists.

8. The semiconductor device fabricating method of claim 7, wherein the e) removing of the semiconductor substrate from the supporting substrate is carried out after the d) forming of the sealing resin layer is carried out.

9. The semiconductor device fabricating method of claim 7, wherein
the a) preparing of the supporting substrate includes aa) forming a plurality of opening portions in the wiring layer,
the e) removing of the semiconductor substrate from the supporting substrate is carried out after the c) placing of the metal plate is carried out,
after the e) removing of the semiconductor substrate from supporting substrate, the b) mounting of a plurality of semiconductor chips on a surface of the wiring layer at a side at which the metal plate is provided so as to seal the opening portions of the wiring layer, is carried out, and
after the b) mounting of the plurality of semiconductor chips, the d) forming of the sealing resin layer is carried out.

10. The semiconductor device fabricating method of claim 7, wherein the sealing resin layer is formed by a molding method or a potting method.

11. The semiconductor device fabricating method of claim 8, wherein
concave portions and/or holes are provided in the frame portion of the metal plate, and
in the d) forming of the sealing resin layer, cutting of the regions at which the frame portion exists is carried out along the concave portions and/or holes that are provided in the frame portion.
